(19) United States
(12) Patent Application Publication
(10) Pub. No.: US 2007/0278629 A1
(43) Pub. Date: Dec. 6, 2007

(54) Method and structure for improving the reliability of leadframe integrated circuit packages

(75) Inventor: Robert M. Smith, Jericho, VT (US)

Correspondence Address: Steven Fischman, Esq.;Scully, Scott, Murphy & Presser, 400 Garden City Plaza, Garden City, NY, 11530, US

(73) Assignee: International Business Machines Corporation, Armonk, NY (US)

(21) Appl. No.: 11/447,830

(22) Filed: Jun. 6, 2006

(51) Int. Cl. H01L 23/495

(52) U.S. Cl. 257/666

(57) ABSTRACT

A method and structure for forming a reliable metallurgical bond during the implementation of a wire bonding process on leadframe-based integrated arrangement, which improves the stress-resistance of a metallurgical bond during and subsequent to a wire bonding process wherein the leadframes of integrated circuit packages utilize a metal plating on recessed regions of the leadframe base or substrate material to which the wires are bonded.

### BACKGROUND OF THE INVENTION

1. Field of the Invention

The present invention relates to a method and structure for forming a reliable metallurgical bond during the implementation of a wire bonding process on leadframe-based integrated circuit packages. More particularly, the present invention relates to a method and arrangement for improving the stress-resistance of a metallurgical bond subsequent to a wire bonding process and follow-on assembly operations wherein the leadframes of integrated circuit packages utilize a metal plating on recessed regions of the leadframe base or substrate material to which the wires are bonded.

Frequently, the structure of integrated circuit packages include leadframes, the substrates of which are provided with metallic plated surfaces, particularly such comprised of silver or gold or other conductive metals or the like, which evidence a poor degree of adhesion to the encapsulating material, the latter of which normally comprises an epoxy, as is well known in the technology. During the processing, which is employed in the assembly of the electronic package, and particularly, the card assembly solder reflow processes, which joins the integrated circuit package to the next level of assembly, high stress levels in both shear and tension are imparted to the integrated circuit package, and consequently, the adhesive bond between the epoxy encapsulant and the plating material on the surface of the integrated circuit package or leadframe may tend to fail due to encountered separation or delamination between these components.

This delamination phenomenon is caused by the highly differing coefficients of thermal expansion between these components, whereby these stresses are generated at their maximum levels in the plane of attachment of the wire bonds and the surface of the plating on the leadframes. These stresses are due to the high temperatures employed during the reflow of the solder connection joining the integrated circuit package to the next level of assembly, typically a PCB, which can cause the delamination of the encapsulant to the silver or gold plating on the leadframe, which can weaken or break the wire bonds due to temperature cycling during normal operation of the integrated circuit.

Heretofore, the problem of the stress failure imparted to the wire bonds has been addressed by minimizing the amount of plating material on the leadframe substrate, which is exposed to the encapsulant or the epoxy material. Thus, for instance, techniques such as spot plating, the addition of specialized coating agents, which enhance the adhesive strengths between the encapsulate, such as the epoxy and the plating material on the leadframe, or adjusting the wire bond parameters or wire diameters in order to enhance the strength of the metallurgical wire bond have met with only relatively limited degrees of success. Although these techniques are workable in various instances in other applications, failures have been encountered, inasmuch as the wire bond area between the surface or plating on the integrated circuit leadframe and the wire bond is normally in the same shear plane in which the maximum shear stresses are generated as a result of potential divergent coefficients of thermal expansion-caused delamination between the plating material and wire bond and that of the encapsulating epoxy material. Although etching and stamping of locking patterns in the leadframe surfaces have been utilized in order to improve the degree of mechanical adhesion between the base leadframe material and the encapsulant, this concept has not been incorporated into the plated areas, which are employed for the wire bonding. Although, to some extent, various aspects of wire bonding in cooperation with the leadframes of integrated circuit packages have been addressed in the technology, none of these are applicable to the inventive concept of improving the reliability of the wire bonds between the components and preventing delamination caused by maximum shear stresses encountered as a result of temperature cycling during fabrication and processing, as well as during normal operation of the integrated circuit package.

2. Discussion of the Prior Art

Lin, et al., U.S. Pat. No. 6,740,576 B1 discloses a method of making a contact terminal with a plated metal peripheral sidewall portion for a semiconductor chip assembly and is primarily directed to providing a redistribution route between a chip pad and the electrical contact terminals. This has nothing in common with a method or arrangement for improving the shear stress-resistant reliability of a wire bond package, which is subjected to high temperature-caused delamination shear stresses.

Lin, U.S. Pat. No. 6,627,824 B1 discloses a support circuit with a tapered-through hole for a semiconductor chip assembly and is directed to a generally complicated process of providing a structure for the redistribution of circuitry and contacts on a surface of a die. This has no relationship with providing a method or arrangement for improving reliability in leadframe integrated circuit packages, so as to obviate or reduce delaminating shear stresses acting on the wire bonds which are connected to the leadframe.

Eldridge, et al., U.S. Pat. No. 6,336,269 B1 is directed to a process of forming spring-like contacts which are generally not fully encapsulated and, consequently, have the ability to move or deform upon the application of stress. This particular patent is utilized for making contacts for sockets and interposers and has no bearing on providing an improved reliability in leadframe-based integrated circuit packages, which are subjected to shear stresses imparted to wire bond connections as a result of delamination between an encapsulant and the leadframe structure.

Bishop, et al., U.S. Pat. No. 6,284,309 B1 describes a method of producing copper surfaces for improved bonding, and the compositions employed for the material. There is no disclosure of providing a method and arrangement for improving reliability in leadframe-based integrated circuit packages, which are subjected to shear stresses cased by delamination between an encapsulant and the leadframe structure, and which would adversely affect the integrity of the wire bond connections thereof.

Finally, Chew, et al., U.S. Pat. No. 5,973,388 describes a leadframe, a method of manufacturing a leadframe, and a method of packaging an electronic component utilizing the leadframe, which provides for a notch at the end of the lead for better mechanical locking of the leadframe to a mold or epoxy compound. This has nothing in common with the present invention in providing a novel method and arrangement for improving reliability in the wire bond connections of leadframe-based integrated circuit packages.

### SUMMARY OF THE INVENTION

Accordingly, in order to improve upon or essentially eliminate any potential problems which may be encountered in maintaining the adhesion between the components of a leadframe with regard to the adhesive bonding between an encapsulant and plating material covering the surface of the leadframe, as a result of stresses generated by delamination between the components which would adversely affect the integrity of any wire bonding connections, the present invention is directed to the displacement from the plated interface between the plating on the leadframe of the integrated circuit package surface to which the wire bonds are connected out of the plane thereof which is deemed sensitive to delamination caused by the greatest horizontal and vertical shear and/or tensile stresses acting thereon. In that instance, the plated, in effect, upper surface of the leadframe, which is required for wire bonding and to which encapsulation is imparted thereto by means of an epoxy, is essentially the plane which is subjected to the highest level of stresses due to the mismatch of coefficients of thermal expansion between the interfacing materials, such as, the encapsulating epoxy and the metallic plating, i.e., such as silver or gold plating material on the surface of the substrate of the integrated circuit leadframe.

Accordingly, pursuant to the inventive concept, by moving the surface of the interconnection between the components, such as the wire bond to the plating on the leadframe surface, out of or recessed from the plane of the surface which is subjected to the greatest stress levels causing delamination, this will minimize the stress on the interface between the encapsulant and the plating material and the wire bond which is connected to the plating material. This, in essence, has the effect of providing localized mechanical locking features, which will reduce the potential of any deleterious delamination between the respective components.

In order to accomplish the foregoing, the present invention contemplates the provision of employing a process of either etching, stamping, or otherwise producing so-called recesses, pockets or wells in the surface of the plating and/or leadframe base material at particular locations where the wire bonds will be attached thereto. Thereafter, the bottoms of the wells and the interior surfaces of the wells are then plated with the desired plating material, and the wire bonding therewith completed, whereby each wire bond or plurality of wire bonds is or are positioned in a respective well possessing peripheral dimensions, depths and locations spaced about the leadframe surfaces specifically designed for that particular wire bond or multiplicity of wire bonds. Thereafter, upon encapsulation of the IC packages with epoxy, delamination will not be encountered to any significant extent within the confines of the well or wells, inasmuch as the wire bond connections in the wells will not be subjected to the high levels of shear or other stresses, which are normally encountered along the interfacing surfaces between the plating and the encapsulant material.

Accordingly, it is an object of the present invention to provide a method for improving the reliability in the wire bond connections of leadframes in integrated circuit packages.

Another object of the present invention resides in the provision of leadframes having recesses or wells formed therein for wire bond connections to reduce the effects of thermal stress-related delaminations adversely affecting the integrity of the wire bonds.

### BRIEF DESCRIPTION OF THE DRAWINGS

Reference may now be made to the following detailed description of preferred embodiments of the invention, taken in conjunction with the accompanying drawings, in which:

FIG. 1A illustrates, generally diagrammatically, a representation of a plated surface of an integrated circuit package leadframe having wires bonded thereto in accordance with the prior art and wherein the surface is normally subjected to high stresses, resulting in delamination phenomena with an encapsulant;

FIG. 1B illustrates, more specifically, a structure in accordance with the prior art, illustrating an embodiment of a leadframe as in FIG. 1A, showing the wire bond connection and encapsulant which are subjected to high delamination stresses;

FIG. 2 illustrates, generally diagrammatically, the surface structure of a leadframe of an integrated circuit package showing the modified recessed configuration for the connection of wire bonds pursuant to the invention;

FIG. 3 illustrates a plan view of a wire bond arrangement pursuant to the invention showing multiple wire bonds connected to a leadframe structure;

FIG. 4 illustrates a step during the fabrication of the leadframe integrated circuit surface pursuant to the invention;

FIG. 5 illustrates a subsequent fabrication step thereof; and

FIG. 6 illustrates the final configuration of the plated well or recessed portion of the leadframe surface, which is in a readiness for wire bonding and encapsulation in accordance with the present invention.

### DETAILED DESCRIPTION OF THE INVENTION

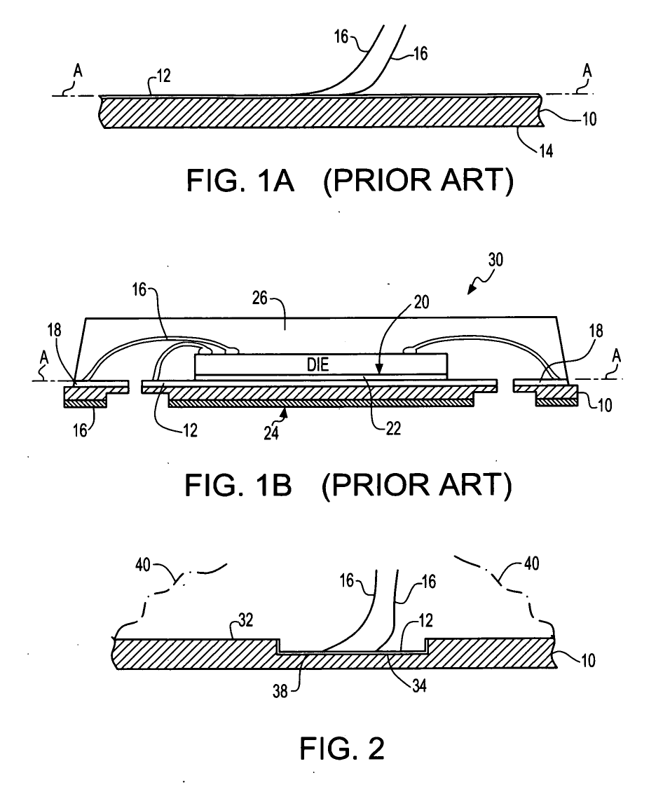

Referring in detail to the drawings, and particularly FIGS. 1A and 1B, both relating to prior art structures for leadframe integrated circuit package wire bond connections, as shown in FIG. 1A, there is generally diagrammatically illustrated a portion of a leadframe 10 having a layer 12 of silver plating covering the surface of a substrate or base material 14, consisting of copper or other suitable leadframe materials or alloys. Connected by bonding to the silver layer 12 pursuant to a usual wire bonding method are metallic wires 16, in this instance, gold wires, with the connections being in the plane “A” of the upper surface 18 of the silver plating layer 12.

For example, as shown in are more specific prior art representation in FIG. 1B of the drawings, the wires 16, which are preferably gold wires, are at one end thereof connected or bonded to the upper surface 18 of the silver plating layer 12 on the copper leadframe 10, the latter of which has a die 20 through attachment material 22 fastened thereto, as is known in the art, and with the gold wires 16 having their upper or opposite ends connected thereto. The bottom surface of the copper leadframe 10 may include an exposed die paddle structure 24, as is known in the technology. The upper surface arrangement of the components, including the gold wires 16, the silver plating layer 12 on the copper leadframe and the die 20 are encapsulated within a suitable mold compound 26, such as an epoxy. This clearly indicates, as illustrated in FIGS. 1A and 1B of the drawings, that the connection or bonding of the gold wires 16 to the silver plating layer 12 on the copper leadframe 10 is located in a plane “A” coinciding with surface 18 covered by the epoxy material or encapsulant 26. Thus, during fabrication and subsequent operation of the integrated circuit package 30 formed by the aforementioned components, which are subjected to extensive heat cycles, due to the highly differing coefficients of thermal expansion of materials, especially between the silver plating layer 12 and the epoxy encapsulant 26, high shear stresses and possibly tensile stresses will be generated between the components at the surface plane “A”; tending to delaminate the epoxy compound 26 from the silver plating layer 12, thereby tending to separate the connections formed by the wire bonds, in effect, pull the gold wires 16 away from the silver plating layer 12, potentially causing a failure of the integrated circuit package or at least adversely affecting the reliability of the wire bonds.

In order to obviate or eliminate the potential delamination problem encountered by the generated high stresses which are at their greatest level at the upper surface of the leadframe 10 and, particularly, plane “A” of the upper surface 18 of the silver plating layer 12 to which they were previously bonded, the gold wires 16; as shown in FIG. 2, there is formed in the unplated surface 32 of the copper material of the leadframe 10 at least one recess or well 34 of suitable size or peripheral dimension. This well or wells 34, rather than the entire upper surface 32 of the leadframe 10 being covered with a silver plating layer 12, only has the silver plating 12 provided within the confines of the well or wells 34 itself or themselves, and with the gold wire or wires 16 being bonded to the bottom 38 of the wells recessed below the upper surface 32 of the leadframe 10. In effect, the wire bonding is recessed below the previous surface plane “A” as shown in FIGS. 1A and 1B.

Thereafter, an epoxy compound or encapsulant 40 is applied so as to encapsulate the entire IC package structure, as is known in the technology. However, in this instance, any thermal stresses which are generated due to differences in coefficients of expansion are at their maximum or highest at the upper unplated surface 32 of the copper leadframe 10, where adhesion is strong, whereas the stresses present at the bottom 38 of the recesses or wells 34 are at a much lower level, thereby increasing the reliability of the wire bond arrangements during subsequent operations irrespective of the encountered temperature cycles to which the leadframe-based IC package is subjected.

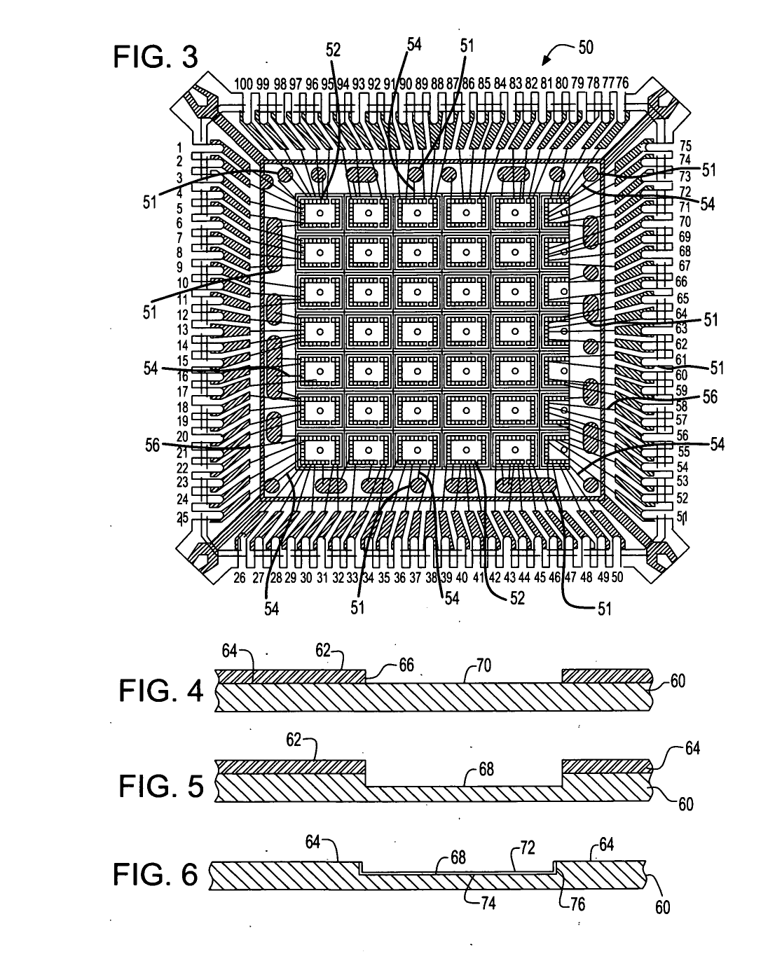

As illustrated in FIG. 3 of the drawings, there is shown a plan view of a typical leadframe 50 showing multiple pockets or wells 51 and multiplicities of wire bond connections 54 extending from the integrated circuit 52 into the respective wells, the latter of which are preferably plated with a metallic layer, such as silver or the like. In this instance, as illustrated by way of example, the leadframe 50, as shown diagrammatically, includes about 44 wire leads from the integrated circuit to the well structures 51, and about 100 wire leads to the exterior package leads 56, although numerous other quantities of wells, of diverse sizes, shapes and numbers of wire leads connected to each respective well may also be contemplated within the scope of the present invention, in conformance with the requirements for a particular integrated circuit package.

Illustrated in FIGS. 4-6 are sequential process steps in implementing the fabrication of the inventive leadframe structure. In this instance, as shown in FIG. 4, the leadframe 60, which is constituted of a copper base material, although other materials can be utilized, has an etching mask 62 applied to the upper surface 64 thereof. The etching mask 62 only allows for an opening 66 in the mask in the region in which a well or recess 68 for effecting the wire bonding is to be formed. The etching mask 62, as may be known in the technology, can be either a mechanical or chemical mask, and only the surface region or area 70 to be etched or recessed as defined by the opening 66 in the mask is subjected to etchant material. This area 70 on the leadframe surface 64 is designed to be as small as possible, but large enough to accommodate the silver plating material employed and to accommodate wire bonding process tolerances.

As shown in FIG. 5 of the drawings, the etchant material is adapted to etch out a well or pocket-like recess 68 (or plurality of wells) of predetermined configuration (or diverse configurations and sizes) in the copper material of the leadframe upper surface 64. Thereafter, as illustrated in FIG. 6 of the drawings, the etching mask 62 is removed from the leadframe 60, in a manner as is known in the technology, and a silver plating layer 72 is applied to only the bottom surfaces 74 and sidewalls 76 in the well or wells 68, with the upper surface 64 of the leadframe copper material of the leadframe 60 remaining in an uncoated or unplated state. This enables the (gold) wires (as shown in FIG. 2) to be bonded to the silver plating layer 72 within the confines of the well or wells 68, and thereafter, encapsulant material applied thereon. In lieu of etching it is also possible to form the wells 68 by means of mechanical processes, such as stamping or the like.

Consequently, by minimizing the silver or metallic plating layer area, as shown in FIG. 6 of the drawings, to the bottom 74 and possibly to the sidewalls 76 of the respective well or recess 68, which has been previously etched or stamped into the upper surface 64 of the copper leadframe 60, and with this area together with the wire bonds having been moved out of the plane subjected to a higher encountered stress, in effect, by being recessed below the surface 64 to which the major portion of the encapsulant is adhered, any potential delamination of the encapsulant with respect to the recessed or well areas will be significantly reduced, thereby improving upon the reliability of the wire bond and resultingly the integrity of the IC package.

Moreover, pursuant to the present invention, by not only reducing the stresses acting on the recessed surfaces for the wire bonding, this produces a more robust package and provides for localized and chemical locking features for the wire bonds into specific recessed regions provided for by the wells in the leadframe.

Although the invention has been described in connection with integrated circuit packages and copper leadframes, it is clearly applicable to all type wire bonds, which are traditionally most susceptible to thermal stress induced delamination failures. Moreover, there may be applicable to C4 or flip chip integrated circuit package connections in order to prevent the failure thereof caused by delamination between encapsulant epoxy materials and the surfaces having the C4 or flip chip connections formed thereon.

While the present invention has been particularly shown and described with respect to preferred embodiments thereof, it will be understood by those skilled in the art that the foregoing and other changes in forms and details may be made without departing from the scope and spirit of the present invention. It is therefore intended that the present invention not be limited to the exact forms and details described and illustrated, but fall within the scope of the appended claims.

What is claimed is:

1. An integrated circuit package including a leadframe; at least one metallic wire bonded to said leadframe; and a dielectric composition encapsulating said at least one metallic wire bond and being in adhesive engagement with a surface of said leadframe in at least a region encompassing said metallic wire bond;
said leadframe having at least one recess formed in said surface region which is encapsulated by said dielectric composition; and
said at least one metallic wire bond having one end thereof extending into said at least one recess, said end of said at least one wire bond being bonded to said leadframe at the bottom of said at least one recess.

2. An integrated circuit package as claimed in claim 1, wherein a conductive metallic layer is plated on at least the bottom surface of said at least one recess, and said at least one wire bond end is bonded to said metallic layer.

3. An integrated circuit package as claimed in claim 2, wherein said conductive metallic layer which is plated on at least the bottom surface of said at least one recess is selected from the group of materials consisting essentially of silver, gold, copper and alloys thereof.

4. An integrated circuit package as claimed in claim 1, wherein said at least one recess has the configuration of an enclosed well receiving said end of said at least one metallic wire bond.

5. An integrated circuit package as claimed in claim 4, wherein said dielectric compound encapsulates said at least one metallic wire bond in said at least one well.

6. An integrated circuit package as claimed in claim 1, wherein said at least one metallic wire is essentially constituted of gold.

7. An integrated circuit package as claimed in claim 1, wherein said leadframe is essentially constituted of copper or other suitable leadframe material.

8. An integrated circuit package as claimed in claim 1, wherein said dielectric composition comprises an epoxy molding compound encapsulating said leadframe and wire bond components.

9. An integrated circuit package as claimed in claim 1, wherein a die is mounted on said surface of the leadframe, said at least one metallic wire of the wire bond having an opposite wire end connected to said die, and said dielectric composition encapsulating said leadframe, wire bond and die.

10. An integrated circuit package as claimed in claim 4, comprising a plurality of said wells being formed in the surface of said leadframe, each of said wells having at least one or a plurality of said wire bonds attached to the bottom thereof.

11. A method of fabricating an integrated circuit package including a leadframe; bonding at least one metallic wire to said leadframe; and providing a dielectric composition for encapsulating said at least metallic wire bond and being in adhesive engagement with a surface of said leadframe in at least a region encompassing said metallic wire bond, said method comprising:
forming at least one recess through selective etching or stamping in said surface region which is encapsulated by said dielectric composition;
positioning one end of said at least one metallic wire bond in said at least one recess; and
bonding said end of said at least one wire bond to said leadframe at the bottom of said at least one recess.

12. A method of fabricating an integrated circuit package as claimed in claim 11, comprising plating a conductive metallic layer on at least the bottom surface of said at least one recess, and bonding said at least one wire end to said metallic layer.

13. A method of fabricating an integrated circuit package as claimed in claim 12, comprising selecting said conductive metallic layer which is plated on at least the bottom surface of said at least one recess from the group of materials essentially consisting of silver, gold, copper and alloys thereof.

14. A method of fabricating an integrated circuit package as claimed in claim 11, wherein said at least one recess is imparted, the configuration of an enclosed well receiving said end of said at least one metallic wire bond and said dielectric compound encapsulates said at least one metallic wire bond.

15. A method of fabricating an integrated circuit package as claimed in claim 11, wherein said at least one metallic wire is essentially constituted of gold, aluminum, copper or other suitable wire.

16. A method of fabricating an integrated circuit package as claimed in claim 11, wherein said leadframe is essentially constituted of copper or other suitable leadframe material.

17. A method of fabricating an integrated circuit package as claimed in claim 11, wherein said dielectric composition comprises an epoxy molding compound encapsulating said leadframe and wire bond components.

18. A method of fabricating an integrated circuit package as claimed in claim 11, wherein a die is mounted on said surface of the leadframe, said at least one metallic wire of the wire bond having an opposite wire end connected to said die, and said dielectric composition encapsulating said leadframe, wire bond and die.

19. A method of fabricating an integrated circuit package as claimed in claim 14, comprising forming a plurality of said wells in the surface of said leadframe, each of said wells having at least one or a plurality of said wire bonds attached to the bottom thereof.

20. A method of fabricating an integrated circuit package as claimed in claim 11, wherein said at least one recess is formed by covering the surface of said leadframe with a mask having at least one opening for defining said at least one recess; and applying an etchant to said at least one opening so as to etch out said at least one recess.
